(19) United States
(12) Patent Application Publication
(10) Pub. No.: US 2015/0219285 A1
(43) Pub. Date: Aug. 6, 2015

(54) Method for manufacturing LED lighting devices and LED lighting devices

(71) Applicant: LIGHTTHERM OY, Oulu (FI)

(72) Inventor: Juha Rantala, Hong Kong (HK)

(73) Assignee: LightTherm Oy, Oulu (FI)

(21) Appl. No.: 14/426,394

(22) PCT Filed: Sep. 5, 2013
(86) PCT No.: PCT/FI2013/050860

§ 371 Date: Mar. 6, 2015

(30) Foreign Application Priority Data
Sep. 8, 2012 (FI) 20125932

(51) Int. Cl. F21K 99/00; H01L 33/62; H01L 33/64; B29C 45/00

(52) U.S. Cl. CPC F21K 9/30; B29C 45/0053; H01L 33/62; H01L 33/647; F21K 9/90; B29L 2031/34

(57) ABSTRACT

A method for manufacturing LED lighting devices and LED lighting devices, wherein connecting means of metallic solderable material to be electrically connected to the anode and cathode of a LED diode component. The connecting means are at least partly embedded into a plastic material, to provide an electrical connection for said LED diode component and a heat sink for its thermal dissipation.

### FIELD OF THE INVENTION

The present invention concerns LED lighting devices. Specifically it concerns a novel method for the manufacture of LED lighting devices, and LED lighting devices produced by the method.

LED lighting components, light engines, lamps and luminaires are increasingly used as light sources in various lighting applications. The reason for this increasing demand for LED usage is their significantly lower power consumption compared to conventional light sources, the absence of harmful chemicals and their outstanding lifetime.

Industry uses LEDs of different power levels in various applications having different levels of technical challenges and limitations. High power LEDs (>1W) are used mainly in applications where high level of lumen output is required from constrained size. Typical applications are filament bulb replacements for power levels of 40W and up, spot lights, track lights etc. Medium power LEDs are used on applications e.g. where different light guides are used for producing even light output on large surfaces.

There are however some technical challenges connected with the manufacture of LED lamps and luminaires. In order to produce high performance and reliable light emitting diode lamps or luminaires, issues of cost, thermal management and management of glare need to be properly addressed. In addition safety requirements may need to be fulfilled, setting demands on various support structures, power supplies and their insulation.

### BACKGROUND OF THE INVENTION

Thermal management is a challenge especially with high power density LEDs. The luminous output of a LED is related to its temperature. A high temperature lowers the optical output power of a LED. The junction temperature in a LED is a function of the electrical power driven into the LED, the ratio of power turned into heat, and thermal resistance to heat dissipation. Main factors affecting the thermal resistance of a LED are its internal thermal resistance, the thermal resistance of electrical and thermal interconnections, the thermal resistance of any heat dissipating (heat sink) structures, and the heat convection capability of the LED's encapsulation. The sum of all thermal resistances in a component multiplied with the thermal power or heat generated, defines how much the temperature rises in the component over the ambient temperature.

A common problem with the semiconductors is the limited heat conduction capability of their interconnection boards' i.e. PCB's electrical interconnections. Typically electrical interconnections on PCBs are of some tens of micrometers thick layers of copper or silver or their alloys. These thin interconnections are poor heat conductors, and do not conduct the heat effectively away from the interconnection. In addition thin interconnections are not connected to heat dissipative structures, they are only used for electrical purposes. An interconnection with a width of 1 mm and a thickness of 35 μm provides a heat transferring cross sectional area of only 0.035 mm². Generally speaking, poor thermal conductivity at the interconnections requires a large area heat sink.

LEDs are typically assembled on different interconnection substrates such as an ordinary printed circuit board (PCB), on a metal core printed circuit board (MCPCB) or on an insulated metal substrate (IMS), or on aluminum oxide or other ceramics substrate, which is typically connected to a ceramic, plastic or aluminum heat sink. Aluminum heat sinks are most broadly used. Ceramic heat sinks make it possible to use different thick film methods to manufacture the interconnections directly on top of the heat sink. Plastic heat sinks are used mainly with MCPCBs on relatively low power solutions. Heat generated at the LED needs to go through the LED package, its solder or glue connections, to its interconnection substrate, through interconnection substrate body e.g. aluminum plate on MCPCB to the heat dissipating body i.e. heat sink. The interconnection substrate's thermal connection to heat dissipating body is often enhanced by different thermal interface materials and different fastening methods, e.g. screws. The prior art LED lighting structures have many parts, and their thermal path consists of several materials on top of each other.

To increase the thermal conductivity, LED components are often provided with a separate thermal pad underneath the semiconductor component. This causes a need for an extra insulating gap on the pad side of the LED, as the two electrical pads need to be insulated with gaps from the thermal pad. This extra insulating gap shrinks down the heat conducting surface area underneath the LED, where the limitations on heat conductivity are most severe and where the heat densities are the highest.

The heat conduction of the interconnection boards can be improved by using so-called thermal slug or heat pad interconnection board solutions, which improve the thermal connection from the component's thermal pad to the MCPCB aluminum body and to heat sinks, including plastic heat sinks.

However, the heat conduction from the LED to the heat dissipating body still remains limited due to the heat transfer limitations of the interconnection board's electrical connections i.e. small cross sectional area of the interconnections and the limited heat transferring electrical and thermal pad area of the component. And the electrical interconnections are always on some sort of dielectric layer having limited heat transfer capacity.

Combining plastic heat sinks with PCBs requires expensive thermal adhesives or greases that require complicated assembly techniques. Form factor problems are also inherent as MCPCB and ceramic PCB are flat and rigid by their nature, making the process of constructing a LED lamp costly and complex as it includes various components, i.e. one or more LEDs, one or more PCBs, thermal interface materials, fasteners such as screws, separate wires or conductors etc. In addition additional heat sink structure enhancing solutions such as heat pipes might be needed. Traditional low cost plastics cannot be applied, due to their limited thermal conductivities, which means high cost and complex to process thermally conductive composites are mandatory to use.

In many LED lighting applications several high power LEDs need to be placed in close configuration, such as Chip on Boards (CoB) or Multi Chip Modules (MCM), or solutions where single or multiple LEDs are driven with high electrical power. Such applications are e.g. spot lights, chip on board LED module structures etc. The heat generating components, their power supplies, the PCBs, the thermal interface materials and solutions, the fixing structures and heat dissipating bodies, all together dictates the achievable performance level in the lighting application. The amount of lumens achievable from the application is a function of the heat transfer capacity of the structure.

It can be concluded that a LED lamp known in the art, made with a plastic casing or heat dissipating body and with a conventional PCB substrate, faces following problems: thermal transfer limitations of the PCB and the plastic body result in heat build-up, increasing LED component temperature, lower LED efficacy and shortened life. These multipart solutions set also challenges for recyclability, when great variety of materials are integrated into one package, partially directed by legislation to be more or less made impossible to be opened easily.

### SUMMARY OF THE INVENTION

The present invention introduces a novel construction of a LED lamp, LED luminaire or LED engine. The inventive lighting device includes electro thermal inserts that provides high heat transfer capacity, low thermal resistance and low ohmic circuitry for the LEDs.

The LED lamp body is made at least partially from injection molded plastic material with the electro thermal inserts at least partly integrated into it. The LED lamp body plastic performs as a dielectric and insulating material between the electro thermal inserts as well as an encapsulation for the circuitry. The plastic LED lamp body works as a heat dissipating structure. There is no need for a separate PCB with its limited heat transfer capacity and e.g. MCPCB metal body, why the inventive LED body can be made low in weight and with low thermal resistance.

The LED lighting structure of the present invention is really simple from its structure, i.e. only two parts are needed in addition to LEDs in order create the LED lighting structure. Those two parts are electro thermal insert and plastic body.

The inventive method for the manufacture of LED lighting devices and the inventive LED lighting devices are characterized by what is said in the appending claims.

### BRIEF DESCRIPTION OF THE DRAWINGS

In the following, the invention and its preferred embodiments will be described in detail with reference to the attached drawings, wherein

FIG. 1 shows in cross-section a LED lamp according to prior art;

FIG. 2 shows in cross-section a LED lamp according to one embodiment of the present invention;

FIG. 3 shows in cross-section a LED lamp according to another embodiment of the present invention;

FIG. 4 shows in cross-section a LED lamp according to still another embodiment of the present invention;

FIG. 5 shows in cross-section a lighting appliance built according to the present invention;

FIG. 6 shows a perspective view of an electro thermal insert intended to carry a multitude of LEDs;

FIG. 7 shows the electro thermal insert of FIG. 6 provided with an injection molded lamp forms;

FIG. 8 shows the electro thermal insert of FIG. 7 being provided with LEDs, lenses and a second plastic cover form underneath;

FIG. 9 shows the assembled structure of FIG. 8;

FIG. 10 shows an embodiment of the invention where the bottom side of the LED lamp carrying structure is covered by a material having good thermal conductivity;

FIG. 11 shows a further embodiment of the inventive electro thermal insert;

FIG. 12 shows a step in the manufacturing process of a LED lamp based on the insert of FIG. 11;

FIG. 13 shows still a further step in the manufacturing process of a LED lamp based on the insert of FIG. 11;

FIG. 14 shows the final LED lamp product of FIGS. 11-13;

FIG. 15 shows a further embodiment of the inventive electro thermal insert;

FIG. 16 shows a step in the manufacturing process of a LED lamp based on the insert of FIG. 15;

FIG. 17 shows still a further step in the manufacturing process of a LED lamp based on the insert of FIG. 15;

FIG. 18 shows a further embodiment of the inventive electro thermal insert;

FIG. 19 shows a step in the manufacturing process of a LED lamp based on the insert of FIG. 18;

FIG. 20 shows another step in the manufacturing process of a LED lamp based on the insert of FIG. 18;

FIG. 21 shows still another step in the manufacturing process of a LED lamp based on the insert of FIG. 18;

FIG. 22 shows the final LED lamp product of FIGS. 18-21;

FIG. 23 shows a further embodiment of the inventive electro thermal insert;

FIG. 24 shows a different embodiment of a thermal insert according to the present invention.

FIG. 25 shows in cross-section a LED lamp according to one embodiment of the present invention high lighting the materials on thermal path

FIG. 26 shows in half of the cross-section a LED lamp according to prior art high lighting the materials on thermal path

### DETAILED DESCRIPTION OF EMBODIMENTS

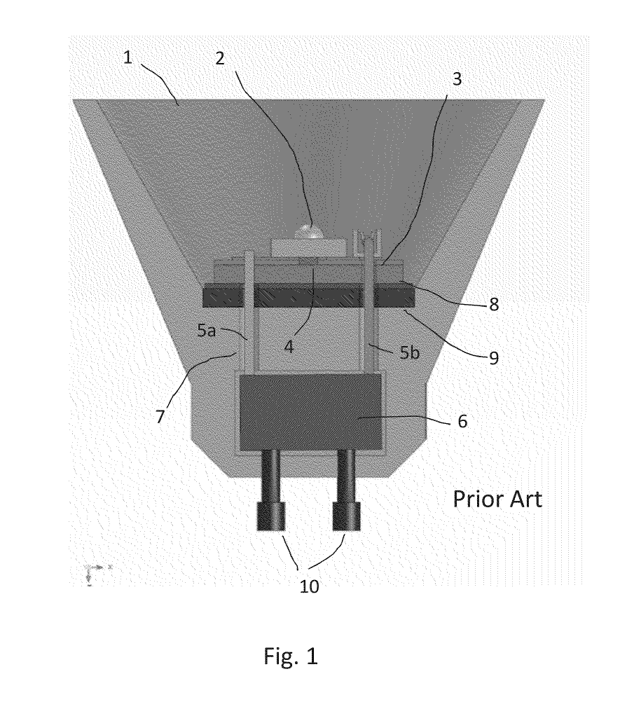

In FIG. 1 is shown a LED lamp according to prior art. The lamp consists of a plastic body 1, a LED 2 with its electrical and thermal pads solder connected to a metal core printed circuit board (MCPCB) 3, electrical interconnections on top of the MCPCB board, a heat pad 4, and a metal base 8. Also integral parts of the lamp are the power supply 6 and the connections 5a and 5b from the power supply 6 to the MCPCB 3. The lamp body 1 needs to have tooled or otherwise manufactured vias 7 to accommodate for the connectors 5a, 5b. The LED lamp is connected to a power source or external circuitry by standardized sockets or pins 10. The task of the in-built power supply 6 is to control the current delivered to the LED, and/or to act as an AC/DC converter.

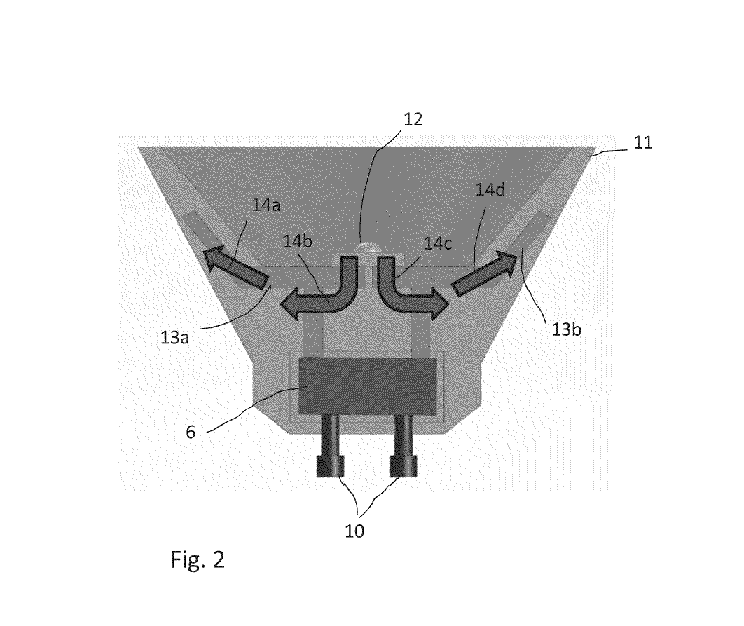

FIG. 2 shows a LED lamp according to the present invention, with a similar plastic overall structure 11 as the one shown in FIG. 1. The LED 12 has here anode and cathode pads (not shown), which are directly soldered to electro thermal inserts 13a and 13b. These inserts act as heat conductors and distributors into the 11 as shown by arrows 14a-14d, and also as connections to the power supply 6 with standardized sockets or pins 10. The electro thermal inserts 13a, 13b provides an efficient and balanced heat transfer towards the heat dissipating surfaces and the ambient environment of the LED lamp. As the highest heat flow density is located underneath the LED, the inventive solution has accordingly removed all thermal interfaces and thermally insulating layers underneath the highest heat flow density, which improves the thermal connection. The power supply 6 can be molded into the structure, or encapsulated in the structure as a result of multiple molding phases or there is a separate opening for the later assembly of the power supply. Different optical functions or sub-functions can also be implemented on the plastic body structure, such as providing receiving means for an optical lens for the LED lamp or implementing reflective optics into the structure.

The inventive electro thermal inserts 13a, 13b are preferably made from copper or solderable copper alloys. Electro thermal inserts can also be made from some coated metal or other high thermal conductivity material. The purpose of coating is to provide solderable surface, and possibly enhance the electrical properties of the insert. It is also possible to coat the insert partially in order to make the coated parts of the insert electrically insulative. This would allow later heat dissipative plastics to be of electrically conductive. Copper ensures low thermal resistance [K/W] and a high heat transfer capacity [Ws/K] and can be easily shaped to follow the shape of the LED lamp body, thus providing large heat dispersing surfaces to the plastic LED lamp body close to the heat dissipating surfaces of the plastic LED lamp body.

The inserts may be formed in 2 or 3 dimensions from a sheet form of copper by cold forging, machining, cutting (laser, water cutting), stamping etc. The electro thermal inserts may be 200 μm to 2 mm thick and at least 1 mm wide, which provides a large cross-sectional area for heat transfer and enables significantly larger heat transfer capacity compared to ordinary e.g. MCPCB electrical interconnections.

The shape of the electro thermal inserts 13a, 13b can be varied for various shapes, as will be discussed later. The width of the electro thermal inserts is preferably at least the width of the electrical pad of the LED component. The electro thermal inserts can be also made of bulk form metal by cold forging, machining, or cutting.

Thanks to the electro thermal insert's high heat transfer capacity and large heat dispersion/conduction capability to the plastic LED lamp body and its heat dissipating surface, it is possible to use relatively low thermal conductivity (<2W/mK or even less than 1W/mK) plastics, which are generally in the low cost price range<<10 ε/kg, and still maintain a high performance level on thermal path.

The high performance thermal path provided by the present invention enables low LED epi chip junction temperatures, allows power epi chip to be used with higher currents and therefore increasing luminous flux of the LED lamp compared to conventional PCB (MCPCB) versions of LED lamps. Furthermore the invention enables easy injection molded manufacturing and shaping of the heat sink lamp body in a smaller form factor. The inventive solution ensures longer lifetime of the lamp and/or the use of LED lamps at higher ambient temperatures than previously.

Molding of plastics is in general lower cost process with greater variety of possibilities than the molding of metal. This provides significant advances for plastic heat sink solutions over the aluminum heat sinks.

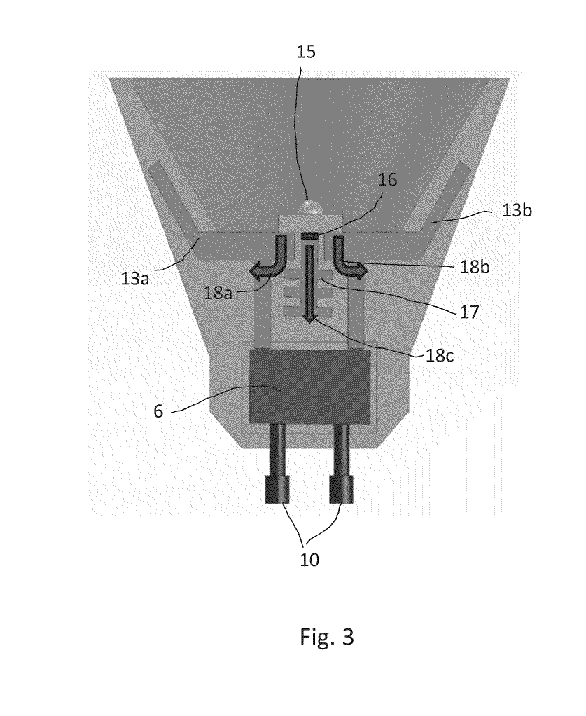

FIG. 3 shows in cross-section a LED lamp according to another embodiment of the present invention, where the underneath the LED 15 is a thermal pad 16 in the same manner as shown in the prior art solution of FIG. 1. A third insert 17, formed with “cooling flanges”, is brought in contact with the thermal pad 16 to act as a thermal insert to further enhance the transfer of the heat from the LED 15. The overall heat transfer pattern as provided by inserts 17 and the electro thermal inserts 13a and 13b is shown by the arrows 18a-c.

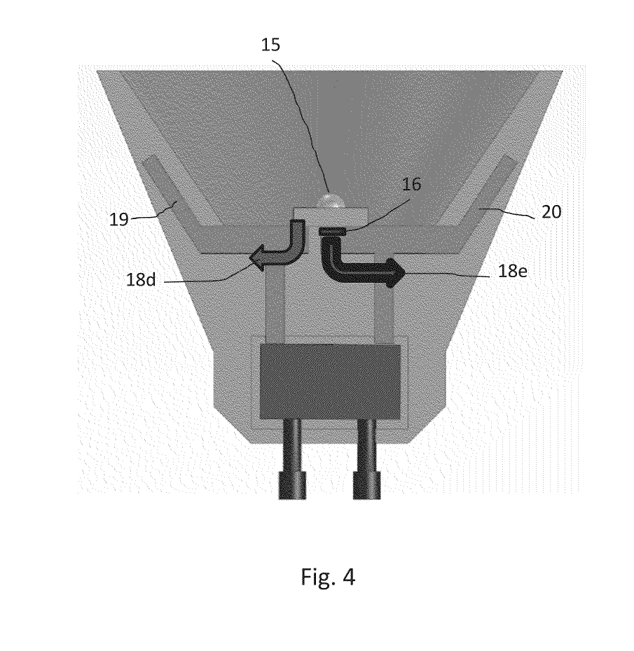

FIG. 4 shows a variant of the embodiment in FIG. 3, where the thermal insert 20 to the right is connected to the thermal pad 16 of the led 15, while the other insert is connected directly to a connection pad of the led 15, as in FIG. 2. The arrows 18d and 18e show the corresponding heat transfer pattern in this case.

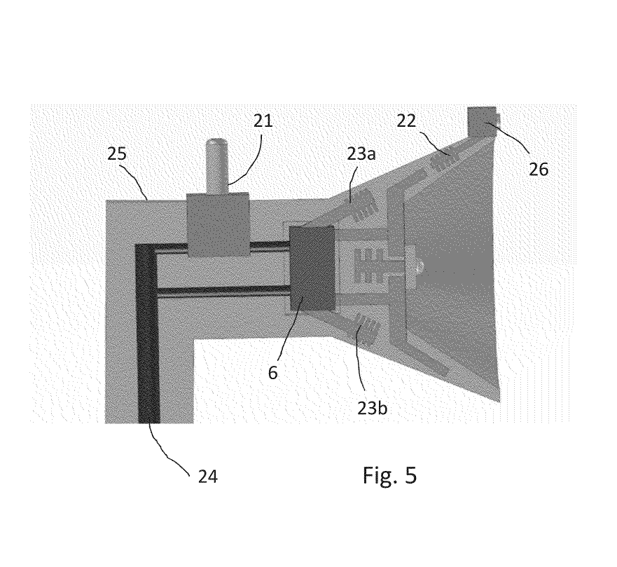

FIG. 5 shows a lighting appliance or end product in the form of a LED torch 25 or the like, with a LED lamp structure like the one in FIG. 3. A sensor 26 for ambient light level or presence detection is provided and an operating switch 21. The sensor 26 and the power supply 6 have their own electrical, electro thermal or just thermal inserts (depending on if an electrical connection is feasible or not) 22,23a,23b. The cabling 24 from power supply 6 goes to a battery or other external power source (not shown).

In the following, a method for manufacturing the inventive LED lighting devices is described.

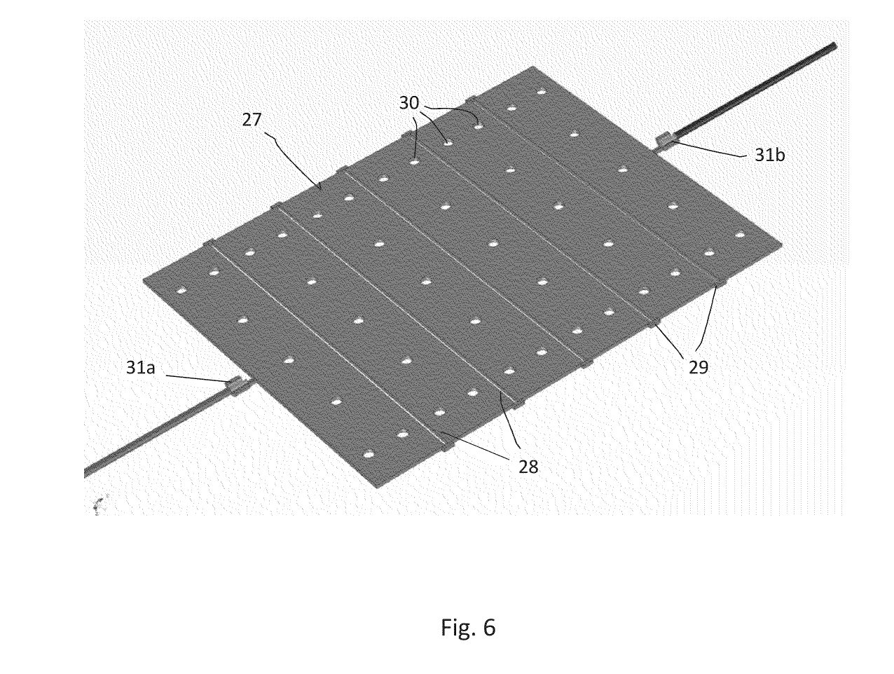

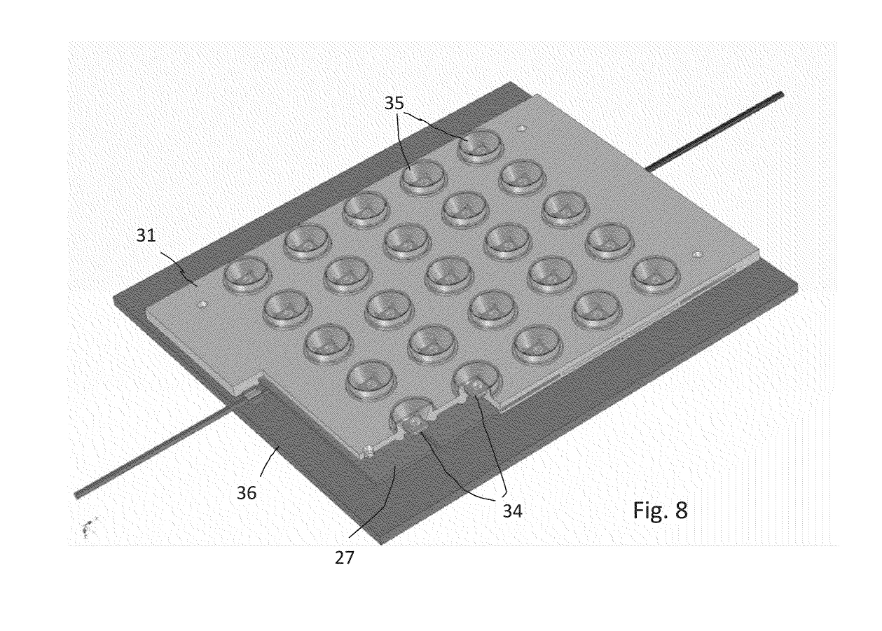

FIG. 6 shows an electro thermal insert 27 for a sheet-formed luminaire carrying a multitude of LEDs (see FIG. 8). There are transverse precuts 28 for the LEDs with short circuiting bridges 29 to stiffen the electro thermal insert and to maintain the gaps between the parts in the insert. The circular holes in the electro thermal are to facilitate plastics adhesion and flow during the injection molding phase. Two electrical connectors 31a, 31b crimped on the insert are 27 also shown. Corrugation, bending or patterning of the sheet can be used in order to improve the mechanical stiffness of the structure.

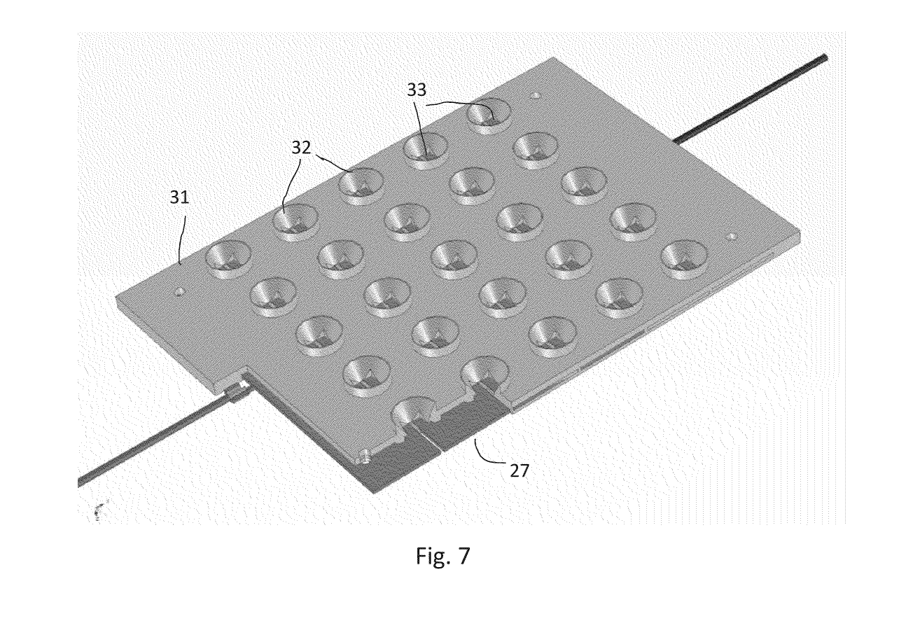

In FIG. 7, injection molding has been carried out in order to form a plastic sheet 31 to form the LED lamps. By injection molding it is possible to form different kinds of optical functions or sub-functions into the LED lamp structure 32. The LED connection pads 33 are left open for later phase LED soldering. It is also possible to do the injection molding on the electro thermal insert 27 having the LEDs already soldered onto the structure. After molding, the short circuiting bridges 29 have been cut away. The electro thermal insert 27 is now ready to form the electrical circuitry.

According to FIG. 8, the LEDs 34 have been soldered onto the structure by conventional means known in the art, e.g. by dispensing solder paste and heating the structure in a reflow or vapor phase oven. If the LED assembly would be done prior to removal of the short circuiting bridges 29 it would be possible to heat the structure to the soldering temperatures by induction. The short circuiting bridges ensure that the induced currents will not go through the LEDs 34 but through the low impedance short circuiting bridges 29 (see FIG. 6).

FIG. 8 also show the LED lenses 35 installed on the plastic sheet 31, and a base metal or metallic heat sink 36 with possible heat dissipating fins attached from its planar upper surface underneath the plastic sheet 31 next to the electro thermal insert sheet 27. The purpose of the base metal 36 is to provide heat conduction away from the injection molded structure and to provide mechanical support and to provide e.g. mechanical sealing mechanism for the structure.

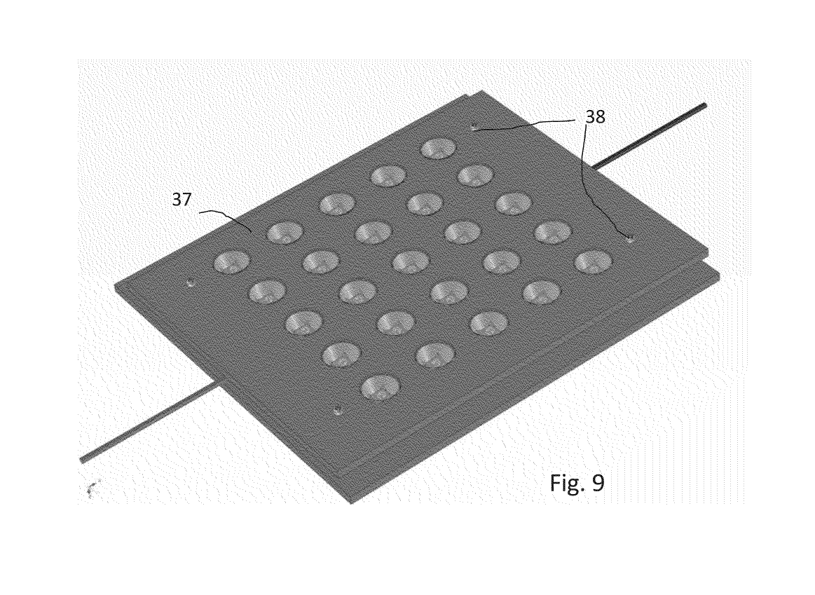

In FIG. 9 is shown the finished sheet form LED luminaire structure. A metal plate or some other high thermal conductivity plate, or a sealing glass plate is attached on the top, to give the lighting appliance an attractive and/or heat dissipating and/or protective finish. The plates are fastened to each other by screws or similar fixtures, it is also possible to seal the structure by fastening and using e.g. different sealants such as O-rings. The fastening provides good thermal connection between all the layers of the product. High ingress protection rating can be obtained by sealing the LED luminaire structure with an O-rings e.g. under the LED lenses, or by using a rubber gasket (not shown) around the edges of the whole sheet. With only slight modifications, the appliance can be made to two-sided by carrying LEDs on both sides.

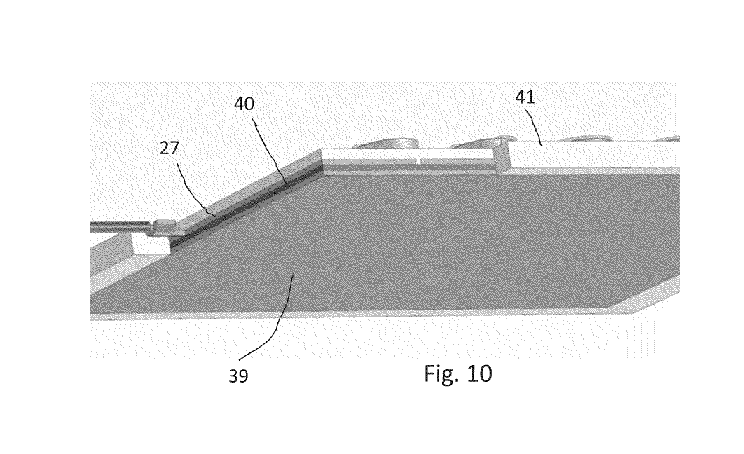

FIG. 10 shows another embodiment of how to seal and connect an inventive LED luminaire structure. In order to provide an external metallic thermal connection for sheet-formed LED luminaire structure, a dielectric layer 40 with high thermal conductivity and heat transfer capacity is laminated, molded or simply painted on the electro thermal insert 27. A second electro thermal insert 39 or layer is then formed underneath. In this way it is possible to arrange a metallic but still electrically isolated thermal connection, to further enhance the thermal connection to the heat dissipating body of the LED luminaire structure. Also the topmost plastic sheet 41 can be formed to close and seal the edges of the planar LED luminaire structure.

According to the present invention, the metal layers inside the plastic structure can also be formed from two separate metal parts that are put next to each other in planar fashion with some dielectric layer in between. The dielectric layer is laminated, sintered, sprayed or deposited by some other known method. Then the insert is soldered to the LED, and the other metallic layer can be connected to a heat dissipating structure with metallic contact, e.g. by soldering or mechanical fastening, or with electrically conductive high thermal conductivity thermal interface materials or glues. The heat from the heat generating LED is then thermally conducted with the metal insert which is electrically isolated, but thermally in good connection with the second metal layer. The second metal layer is in turn thermally in good, preferably metallic, connection with the heat dissipating structure of the LED lamp.

The present manufacturing method makes it possible to include various features in a LED lamp body, such as circuitry for sensors, optics or optical sub functions or sealing mechanisms for the LED lamp. The inventive construction provides safety distances from the power supply and from the electrical mains voltage supplies. According to the invention, properties of the plastic material can be selected to have high emissivity on thermal wavelengths, in order to increase the heat radiation. Plastic materials properties can also be tailored in order to provide high reflectance on optical wavelengths, which can be used to implement lighting mixing chambers. Furthermore, the plastic can be filled with electromagnetic absorbers to improve lamp's electromagnetic compatibility.

The present LED lamp construction simplifies the LED lamp construction from ordinary solutions, e.g. separate PCBs for the LEDs are not required, there is no need for thermal interface greases, there is no need for screws or similar for fixing the LED PCB to the structure in order to provide good thermal connections. The plastic body of the present structure can have several properties that normally require separate parts, such as insulating shields between the power supply and the electrically conductive aluminum heat sink. The plastic body provides several other functions at the same time being dielectric material between electrical interconnections', being supporting structure for the electro thermal insert providing means for e.g. 3D structures etc.

Manufacturing of the present LED lamp construction with injection molding can be done easily and economically using standard industrial manufacturing equipment. The basic principles of the invention works also on plastic LED luminaire and plastic LED engine solutions and is therefore not limited to any size or form of the conventional LED lamp or LED luminaire.

The present invention can be used with packaged LEDs and with LED chips, epis, or dies. Packaged LEDs are soldered, or they can be glued, whereas the LED chips/epis/dies are die bonded and/or wire bonded to the structures following the basic idea of the present invention. The electro thermal insert structures support the use of different bonding procedures known in the art. The inserts can be coated for supporting e.g. eutectic bonding procedures for die bonding. LED chip/epi/die structures preferably require glob-topping technique well known in the art.

Obviously there are several process orders and modifications for the manufacturing of the electro thermal insert structures. The order of performing the process steps need not always be the same, and materials and process parameters may vary according to the application.

With this inventive electro thermal inserts different sheet metal manufacturing methods can be applied and the electro thermal insert structures can get their LEDs mainly by using normal 2D electronics manufacturing processes. Flat 2D sheet metal piece or panel behaves in a similar way in SMT (surface mount technology) processes, die bonding and wire bonding processes as normal e.g. FR4 printed circuit board does. Solder paste printing or dispensing or jet printing, pick and place process and reflow soldering are quite similar than with normal PCBs. There are only small differences, processes and parameters, like temperature profiles in reflow oven that must be adjusted for the sheet metal parts. Sheet metal pre-cut inserts can be manufactured in larger panels that consist of several insert preforms, like normal small size FR4 PCBs can be processed. That so called panelling method increases productivity and throughput of the process lines.

Nowadays 3D electronics is pushing through to the high volume electronics market. With LPKF's LDS (Laser direct structuring) technology it is possible to manufacture 3D conductor lines on top of the free form plastic parts. This kind of electrical structures are used e.g. for vehicles, like autos and motorcycles, where 3D structures minimizes normal cabling work. Generalization of LDS structures has increased also need for 3D assembly lines of SMT components. Nowadays several manufacturers are producing robotized pick and place lines or cells. These kinds of 3D lines are not as fast and capable for high volume production as 2D production lines are. Consumer LED lighting products are usually extremely high volume products. It is beneficial if 2D processes can be used for this kind of products. With this inventive sheet metal electro thermal manufacturing process approach this is possible. However, existing 3D processes can be fully exploited with the structures following present invention.

In mechanics industry sheet metal work is also well known and widely used method for manufacturing complicated 3D parts. It is relatively easy and cost efficient to manufacture complicated electro thermal inserts where LED components or dies can be in free 3D positions. That makes it easier to design the light output of the LED lamps or luminaires or LED engines to fulfill the demands of different lighting cases. It also gives more degrees of freedom for industrial designers of the LED lamps or luminaires engines.

With the improved thermal path, it is possible to create LED lighting structures, which heat sinks run so hot, that the heat radiation plays already a significant role in heat dissipation. This enables sealed structures where the LED structure's heat dissipation happens by radiation. With electro thermal inserts it is also possible to conduct heat efficiently away from sealed structures, which is beneficiary e.g. on outdoor LED lighting structures.

In order to clarify the various and versatile alternatives offered by the present invention a number of non-limiting working examples will be provided.

### Example 1

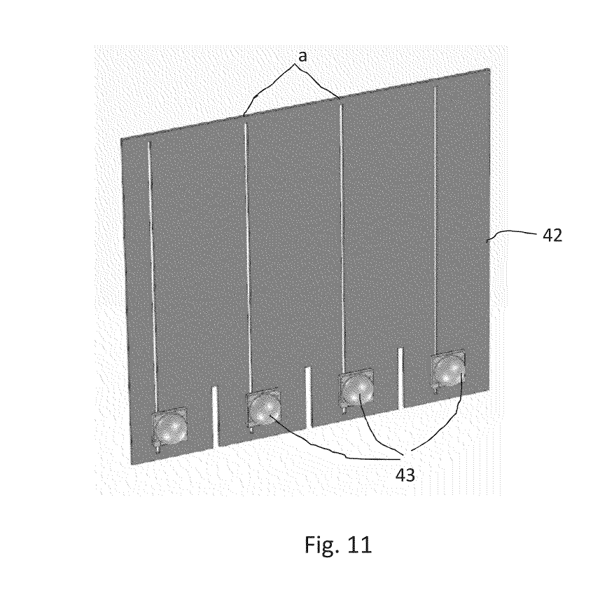

In FIG. 11 is shown an electro thermal copper insert 42, much like the one in FIG. 6. An assembly of four LEDs 43 is soldered across narrow cutouts in the copper sheet. The sheet is now short-circuited (copper bridges a), in order to keep it in one piece.

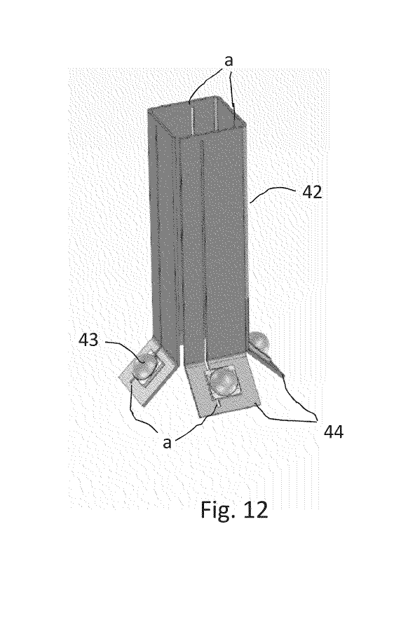

In FIG. 12, the insert 42 has been bent into a pipe form with a square cross-section, having one LED 43 at the end 44 of each of the four sides. The ends 44 have been bent outwards. The eight short-circuits a are still present in the sheet.

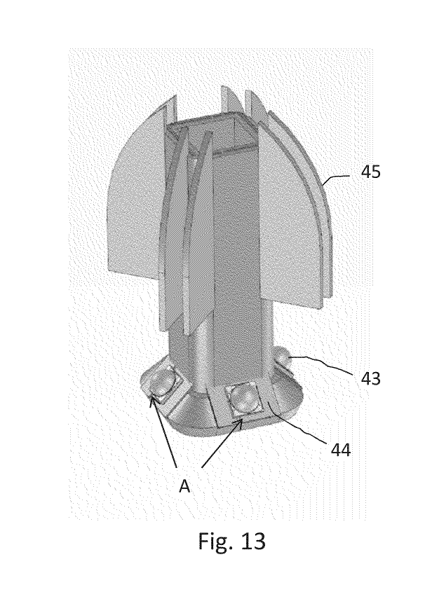

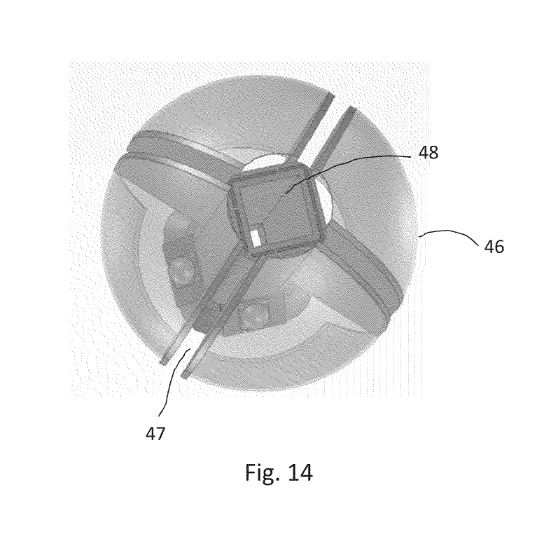

FIG. 13 shows the insert of FIG. 12 as injection molded into a lamp body 45 of plastic material. All short-circuits are removed, see arrow A, for example. FIG. 14 shows the final product, a luminaire or lighting appliance, having a shader or screen 46 put on top of the plastic lamp body 45. The lamp body provides air openings 47 for heat dissipation, and the power supply can be fitted in the cavity 48 of the square-formed tube.

### Example 2

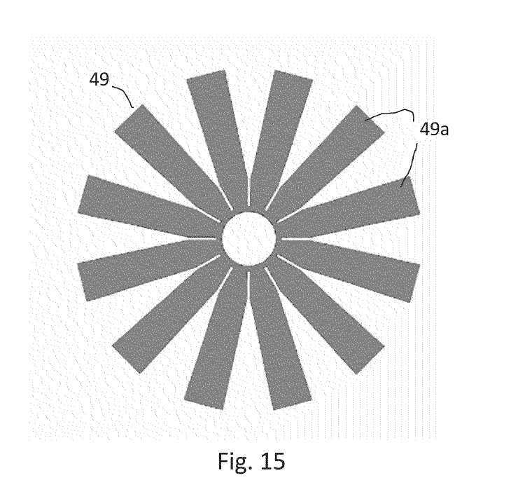

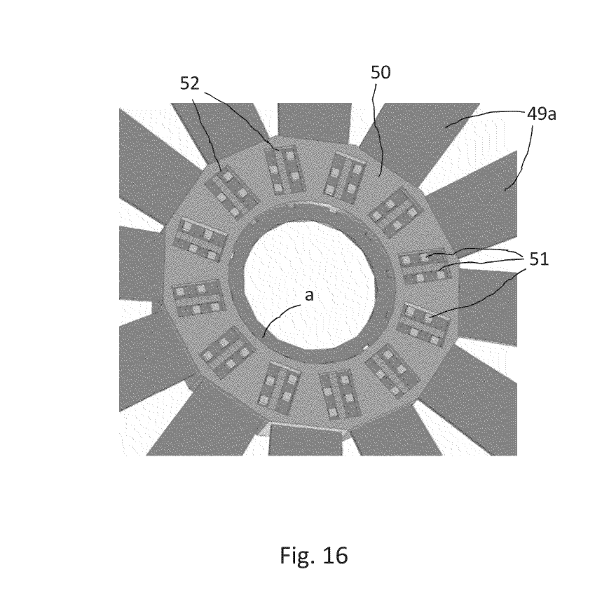

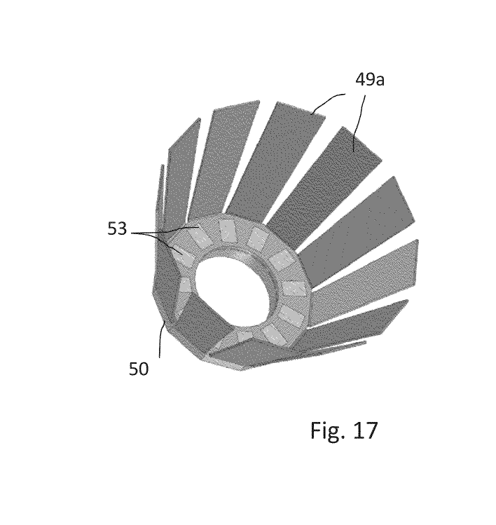

FIG. 15 shows a copper billet 49 with petal-like wings 49a. In the enlarged view of FIG. 16, the billet 49 has been injection molded with an annular plastic support structure 50 on both sides. Again, the electro thermal insert formed by the billet is short-circuited (a). Cutouts 51 in the plastic support structure have been provided, so that the copper is accessible for soldering and wiring LED components 52 across the billet wings 49a. FIG. 17 shows a thermal insert ready for injection molding to be a powerful spotlight or the like. The wings 49a have been bent, the short-circuit has been removed (arrow A), and the blue LED components and their wiring have been covered with a protective silicon-based glob-topping 53 containing phosphor. Phosphor is used to produce white light. Such glob-topping and LED light conversion is well known in the art.

### Example 3

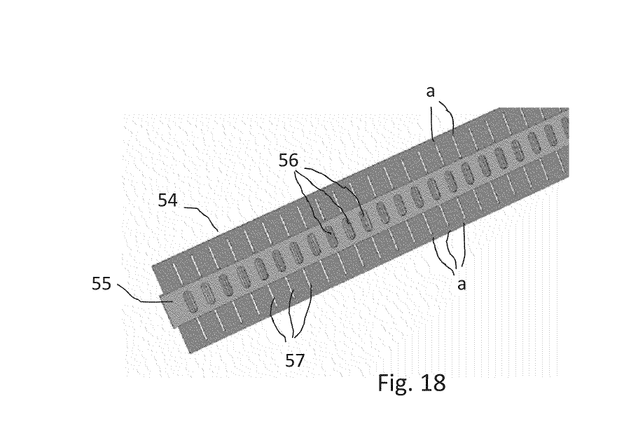

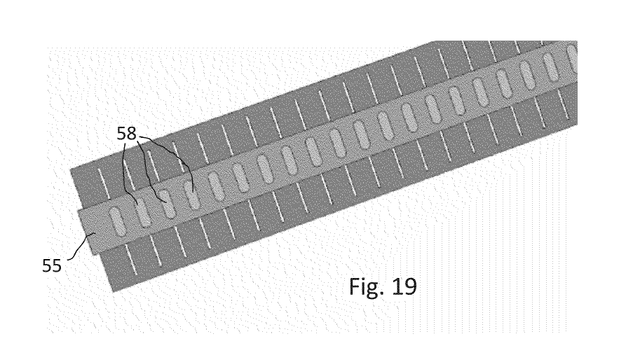

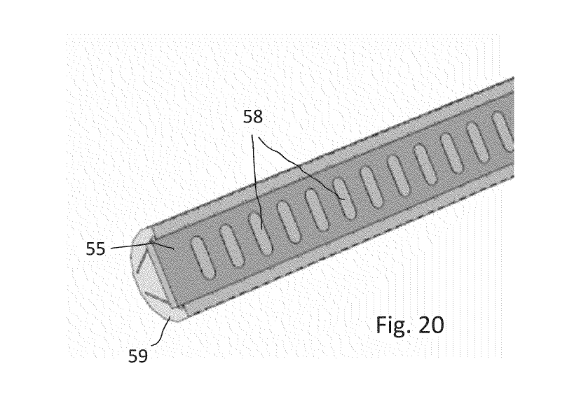

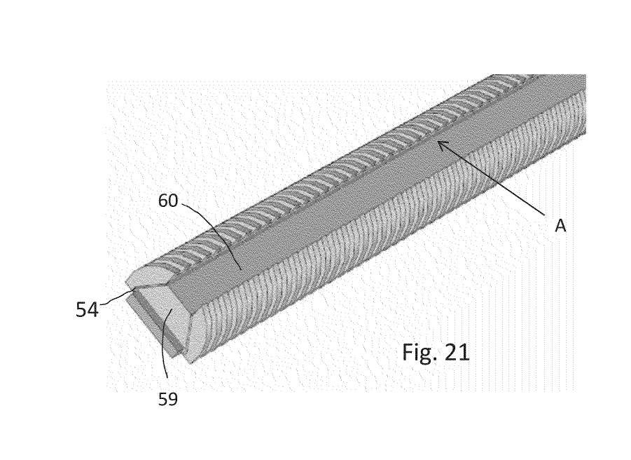

In FIG. 18 is shown a strip-like electro thermal insert 54 with short-circuits a of the same kind as in the previous examples. It has been injection molded from both sides with a stiffening plastic strip 55, having apertures 56 for the LEDs to be connected across the slits 57 in the insert 54. In FIG. 19, the LED components have been wired, soldered and glob-topped 58 as in FIG. 17. In FIG. 20, the insert 54 and the plastic strip has been further injection molded into an elongate plastic body 59. In FIG. 21 is shown how the shortcuts are machined away by cutting a slot 60 in the back of the plastic body 59 that is deep enough to remove the short-circuits (arrow A) a from both sides of the insert 54.

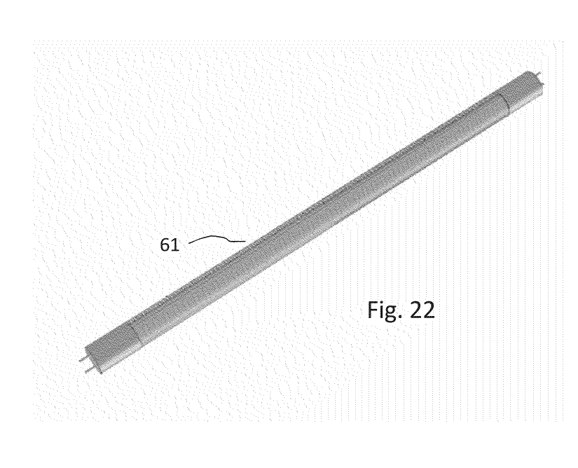

FIG. 22 shows the final product, in this case a LED-based fluorescent tube 61.

### Example 4

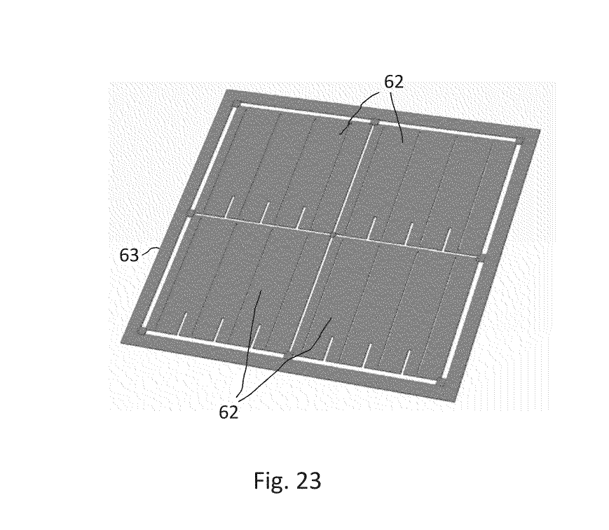

FIG. 23 shows how several inserts 62 can be manufactured out of one copper plate 63. The panel form of electro thermal inserts can be put to injection molding in order to form e.g. stiffening structures as in FIG. 16 in parallel fashion.

In the highest power LED solutions with the electro thermal inserts and plastics mold, the plastics heat transfer capacity becomes an issue. In order to increase the heat transfer capacity of dissipating structures, it is possible to combine different molding techniques and different materials. For example, the electro thermal inserts molded in plastic can be molded only partly, and made with only small thicknesses of plastic material. Such a small thickness of plastics provides the only the necessary electrical insulation. This molded combination of electro thermal insert and thin plastic can be seen as an insert to a second mold, where a heat dissipating structure will be molded over the combined insert. The combined high thermal conductivity and high heat transfer capacity electro thermal insert partially molded in plastic can also include other functions like connections to power supplies, the electro thermal inserts in the structure create the electrical circuit structures for the heat generating electrical parts, i.e. LEDs and circuit structures for other components, e.g. for power supply capacitors, for possible sensors in the LED lamp or LED luminaire structure.

An alternative embodiment of the invention is to make such a second molding with grapheme or graphite or porous graphite. Graphite materials have thermal conductivities in the range of 200-800W/mK, and even porous graphite provide better than 100W/mK thermal conductivity. These values are much higher than high thermal conductivity plastics can provide, which is in the order of 20W/mK. Graphite or grapheme blended plastics can provide higher thermal conductivities and can be used as an electrically and high thermal conductive body of an inventive LED lamp or LED luminaire or heat sink. The embodiment does not depend on the process order, i.e. thermally high conductive body can be molded first and the plastic electro thermal insert and possible thermal insert may be molded inside the thermally high conductive body later.

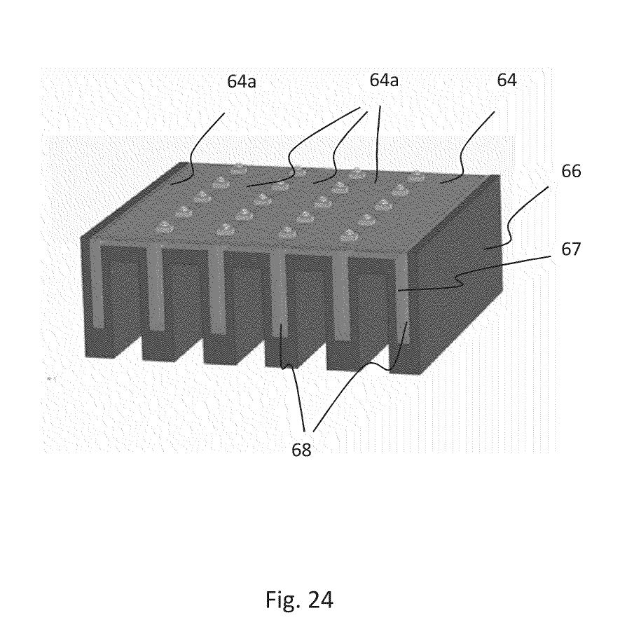

Reference is made to FIG. 24, where a structure of the above kind is shown. The electro thermal insert 64 consists here of a number of U-shaped elements 64a, which flanges 68 extend downwards in the figure. The LED diode components are placed across the slits between the elements 64a of the insert 64. The insert 64 is injection molded in a plastic body 67, which in turn are molded in a graphite structure 66. The upper structure of the LED lamps with reflectors etc. is not shown.

In this way also e.g. aluminum bodies can be combined with an electro thermal insert plastic body combination. These combinations enable high power density structures such as spot lights, spot luminaires, canopy light, high bay luminaires etc.

### Example 5

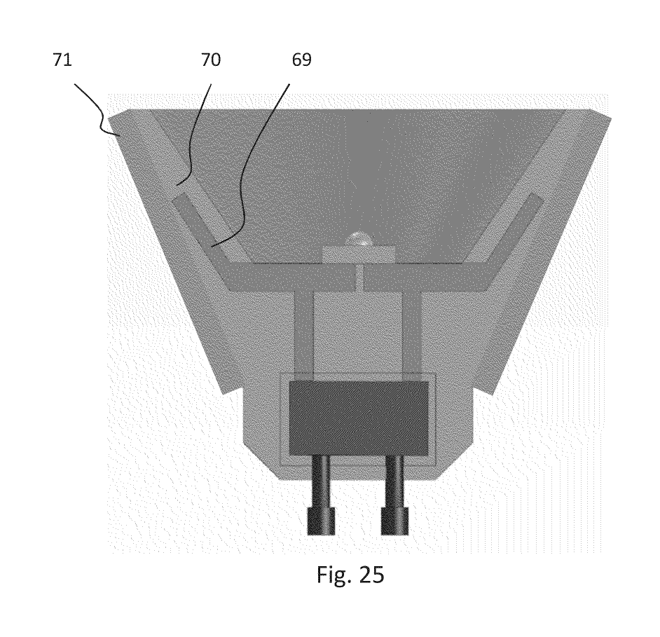

FIG. 25 shows the materials on thermal path from metal insert's LED electrical pad interconnection surface to heat dissipating surface of the plastic LED lighting structure. Electro thermal insert 69 is the metal part in heat path, and plastic 70 is the plastic body of the LED lamp. 71 is another material molded in the heat dissipating structure.

Thus there are one metal part on the total thermal path and maximally the same amount of materials as there are number of moldings done on to the LED lighting structure. LED lighting structure has partially one plastic material and partially two materials on its thermal path in addition to electro thermal insert.

One material in present invention means one material or material blend molded with one molding step. Different thin coatings can be applied on top of e.g. electro thermal insert e.g. for making the insert solderable, and these coatings do not effect on the thermal path's operation noticeably. The same withstands e.g. for painted heat dissipating body of the LED lighting structure of the present invention. These thin layers are not considered as materials on thermal path. In addition it is possible to make the metal insert from various metals, metal blends such as bronze or brass and or metal parts which are e.g. welded or soldered or bonded with some method known in the art into one metallic insert structure, and obviously belong under the present invention.

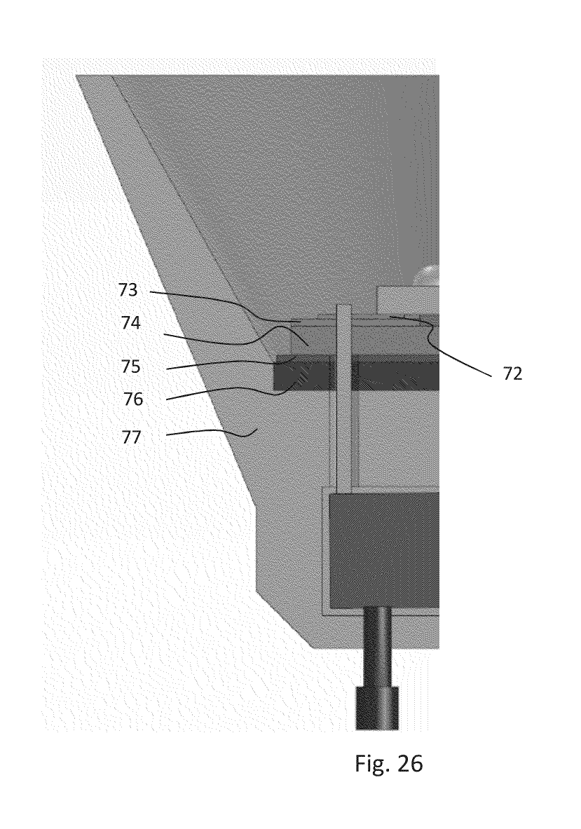

FIG. 26 shows in half of the cross-section of a LED lamp thermal path according to prior art. The thermal path is presented from PCB's electrical interconnection surface to heat dissipating surface of the plastic LED lighting structure. On the thermal path there are electrical conductor 72 on MCPCB, dielectric layer on MCPCB 73, metal body of the MCPCB 74, thermal interface material 75, heat dispersing insert 76, and plastic heat sink body 77. I.e. on the total thermal path there are six materials, in order to reach high performance LED lighting structure with known methods.

The integrated LED lamp body solution according to the invention with integrated interconnections is so powerful that relatively small amount of graphite doping of the plastics is needed in order to reach the thermal performance level of state of the art metal heat sink based LED lamps, which reduces costs significantly. The integrated LED lamp bodies are also very light weight solutions, thanks to smaller relative mass of plastics compared to metal and reduced number of parts are required.

The LED lighting structure of the present invention can be LED lamp, part of the LED lamp, LED luminaire, part of the LED luminaire, LED engine, decorative element having lighting function, structure having lighting function or some other similar lighting structure where the structure described in appended claims can be utilized.

The LED engine is a light emitting structure from which whole luminaire can be built easily, e.g. adding just power supply, luminaire stand and luminaire shade. The LED engine provides electrical and thermal interconnections for the LED and provides the heat dissipating structure. The LED engine is thus like a lamp, but it does not have the standardized socket. LED engine can have the power supply integrated or the power supply can be located outside from the structure.

The LED lamp is a LED lighting structure which has some standardized socket such as E14, E27, GU10, MR16 or some other. LED lamp usually has a power supply integrated but when e.g. so called AC-LEDs are used there is no need for separate power supply. LED lighting structure of the present invention can also consist of several subassemblies, each of which has at least the LEDs and the electrical and thermal interconnections as well as heat dissipating body.

Plastic material can have a wide variety of functions, which are beneficiary for the LED lighting structure. The different beneficiary functions implemented by plastics can be implemented on the structures in question during the first or later molding phases.

With plastics it is possible to implement different kind of optical properties. With opaque plastics it is possible to implement different optical properties and functions. Plastics' reflective properties can be varied e.g. by doping and optical functions such as reflectors can be created. Different refractive index properties can be produced e.g. with different plastics providing access to refractive optical solutions. Different plastics have different thermal properties and by using e.g. graphite doping or glass fiber doping plastics' thermal properties can be tailored. There are also dopants for the plastics that can be of lower cost level than the basic plastic is, good example being talc, which is used for increasing thermal conductivity and lowering the material costs on the structure. Same withstands with mechanical properties, and e.g. with glass fiber doping high mechanical strength and stiffness can be reached.

It is advantageous to use high flow ability plastics on manufacturing e.g. small feature sizes on the structures of the present invention. E.g. heat dissipating structure's surface area can be increased by utilizing different micro structures, e.g. grooving and in order to manufacture these small feature sizes, it is beneficiary to use high flow ability plastics.

Since the LED lighting structures in question can be manufactured in different process phases, it is possible e.g. to do the first molding with plastics that withstand the temperatures of the soldering processes, and this structure can be used as an insert on later molding phase where e.g. the heat dissipating body, with higher plastics volume can be done with some really low cost plastic in order to cut cost from the structures in question.

There is a big room for cost optimization on using low cost plastics also e.g. inside the structure and e.g. the outer surfaces are made with materials fulfilling e.g. different regulatory requirements such as flammability or hardness requirements. With different plastics it is also possible to control the thermal expansion effects of the structure. E.g. one can use flexible materials in places where there are biggest structural deformations from the LED lighting structures thermal expansions. Different plastics properties can also be utilized on implementing e.g. press fit sealing for external optics.

By several injection molding phases it is also possible to create completely sealed structures in order to implement high ingress protection class LED lighting structures. E.g. by first injection molding one can create the heat dissipating structure, into which structure e.g. power supplies and LEDs are assembled and this structure is then sealed by using separate optics as an insert for second phase molding where the optics will be molded from its edges to the former molded heat dissipating structure, and a completely sealed LED lighting structure was created. Naturally different plastics have different outlooks, and the outlooks of the plastic can be tuned by doping. E.g. the color of the plastic can be changed in a broad category, and of course there are different base colors on the plastics. For LED lighting structures it would be beneficiary to have different grapping surfaces, e.g. for steering the light beam of the luminaire, and by suitable e.g. rubber like plastics this feature can be implemented during some molding phase of the LED luminaire structure. One aspect in here is the touch feeling, and by plastics it is possible to control the touch feeling of warm or hot structures, once again beneficiary e.g. on steering the light beam of the luminaire by taking the hold from the heat dissipating part of the LED luminaire. Plastics can have high thermal emissivity and it is beneficiary for heat dissipating structures to have high thermal radiance, thus by injection molding the heat dissipating structures outermost surfaces it is possible to increase the radiated heat.

With different plastics led lighting structure e.g. LED lamp can be made easier to be assembled to lamp fixture or to any other mechanical and/or electrical fastener. Another injection molding can be used to add new plastic material to get better in-flammability properties of the LED lighting structure to e.g. fulfill the safety regulations. The next injection molded plastic material can also be added to increase hardness and durability against impacts or resistance against wearing of the surface of the LED lighting structure to withstand mechanical stresses during usage of the final LED lighting product. Also yield strength of the LED lighting structure can be improved by adding another stronger plastic to the LED lighting structure. The surface of the LED lighting structure can be made self-cleaning by adding suitable plastic, doping and suitable surface profile to it. The surface can also be made water, grease or dirt repellent by injection molding and adding suitable plastic or suitably doped plastic on top of the first plastic.

It is clear to one skilled in the art that the invention is not confined to the embodiments and examples presented above, but can vary freely within the scope of the appended claims.

The following represents, in summary, a number of preferred embodiments of the present technology:

A method for manufacturing LED lighting devices, comprising the steps of
providing connecting means for at least one LED diode component, said connecting means being of metallic solderable material to be electrically connected to the anode and cathode of said LED diode component;
connecting said LED component to said connecting means by soldering; and
embedding said connecting means at least partly into a plastic material to provide an electrical connection for said LED diode component and a heat sink for its thermal dissipation.

The method can be carried out by such that the LED diode components are connected across slits provided between partitions of said connecting means.

In another embodiment, the partitions of the connecting means are bent to a shape required by the design of said LED lighting device.

In a further embodiment, the connecting means are combined with a second plastic material to produce the final LED lighting device.

In still a further embodiment of the method, the combining of said connecting means with said second plastic material is done by injection molding.

In still another embodiment, the outer surface of the second plastic material is at least partly covered by a material having good thermal conductivity, such as metal, graphite or grapheme.

All the above embodiments can be combined.

The present technology provides an LED lighting device, comprising of at least one LED diode component and a plastic body, wherein the electrodes of the LED diode are connected to metallic connecting means being at least partly embedded in said plastic body, the inserts acting both as electrical connectors for said LED diode and as heat sinks for its thermal dissipation.

1. A plastic Light Emitting Diode (LED) lighting structure having a plastic surface, said structure comprising:
at least one LED,
at least one metal insert having an electrical interconnection surface providing electrical
interconnections for the at least one LED, wherein the at least one metal insert is a heat conductor and distributor from the at least one LED into the plastic LED lighting structure,
where the plastic LED lighting structure is injection molded of at least one plastic material and the plastic surface convects, radiates and conducts heat generated at LED lighting structure, and
wherein there are a maximum of two materials in a thermal path from the electrical interconnection surface of the metal insert to a heat dissipating surface of the plastic LED lighting structure.

2. The plastic LED lighting structure according to claim 1, wherein the at least one plastic has a thermal conductivity smaller than 2W/mK.

3. The plastic LED lighting structure according to claim 1, wherein the metal insert provides heat transfer to the heat dissipating surfaces following the shape of the LED lighting structure.

4. The plastic LED lighting structure according to claim 1, wherein the metal insert is thicker than 200 μm at LED interconnections of the electrical interconnection surface.

5. The plastic LED lighting structure according to claim 1, wherein the metal insertis Copper.

6. The plastic LED lighting structure according to claim 1, wherein the metal insert is an electro thermal insert, providing both electrical and thermal interconnection for LED pads.

7. The plastic LED lighting structure according to claim 6, wherein the at least one LED is soldered to the electro thermal inserts.

8. (canceled)

9. The plastic LED lighting structure according to claim 1, wherein the at least one LED chip is die bonded, wire bonded, and glob-topped to the metal insert.

10. (canceled)

11. (canceled)

12. The plastic LED lighting structure according to claim 1, further comprising high thermal emissivity plastics at least partially covering a molded LED insert structure capable of providing improved heat dissipating body thermal emittance.

13. A method of manufacturing a plastic Light Emitting Diode (LED) lighting structure comprising the steps of:
molding a metal insert at least partially inside a plastic in a first phase,
creating a heat dissipating plastic surface by injection molding, and
attaching at least one LED onto a surface of the metal insert,
wherein a maximum of materials form a thermal path from an electrical interconnection surface of the metal insert to the heat dissipating surface with the metal insert arranged partially inside of the plastic.

14. AThe method according to claim 13, wherein the metal insert is made from precut sheet metal or by cold forging.

15. (canceled)

16. The method according to claim 1, wherein further comprising:
short circuiting metal parts of the precut sheet metal before the injection molding; and
cutting the short circuited metal inserts into at least two pieces after the injection molding to provide functional circuitry for the plastic LED lighting structure.

17. The method according to claim 16, wherein the at least one LED is attached to the metal inserts before the short circuits are removed from the plastic LED lighting structure.

18. The method according to claim 16, wherein the at least, one LED is attached to the metal insert after the short circuits are removed from the plastic LED lighting structure.

19. AThe method according to claim 16, wherein the metal parts of the metal insert are bent to 3D shape according to thermal or optical demands of the plastic LED lighting structure.

20. (canceled)

21. The method according to claim 13, wherein at least one LED attached onto the metal insert is an LED chip, which is die bonded, wire bonded and glob-topped onto the metal insert before injection molding.

22. The method according to claim 13, wherein at least one LED attached onto the metal insert is LED chip, which is die bonded, wire bonded and glob-topped onto the metal insert after injection molding.

23. The method according to claim 13, wherein at least one LED attached onto the metal insert is a packaged LED component, which is soldered onto the metal insert before injection molding.

24. The method according to claim 13, wherein at least one LED attached onto the metal insert is a packaged LED component, which is soldered onto the metal insert after injection molding.

25. The method according to claim 13, further comprising a second injection molding phase wherein more plastic is added by another injection to achieve a greater heat dissipating surface.
